(19) United States
(12) Patent Application Publication
(10) Pub. No.: US 2012/0220127 A1
(43) Pub. Date: Aug. 30, 2012

(54) MANUFACTURING METHOD OF SEMICONDUCTOR DEVICE

(75) Inventor: Tsutomu Komatani, Kanagawa (JP)

(73) Assignee: SUMITOMO ELECTRIC DEVICE INNOVATIONS, INC., Yokohama-shi (JP)

(21) Appl. No.: 13/406,917

(22) Filed: Feb. 28, 2012

(30) Foreign Application Priority Data
Feb. 28, 2011 (JP) 2011-042941

(51) Int. Cl. H01L 21/3205

(52) U.S. Cl. 438/686; 257/E21.295

(57) ABSTRACT

A manufacturing method of a semiconductor device includes: forming a metal layer having a surface containing gold; growing a first silicon nitride layer in contact with the metal layer by a plasma-enhanced vapor deposition method; growing a second silicon nitride layer in contact with the first silicon nitride layer by a plasma-enhanced vapor deposition method at a layer-forming rate higher than that of the first silicon nitride layer, the second silicon nitride layer having a silicon composition ratio smaller than that of the first silicon nitride layer.

### CROSS-REFERENCE TO RELATED APPLICATION

This application is based upon and claims the benefit of priority of the prior Japanese Patent Application No. 2011-042941, filed on Feb. 28, 2011, the entire contents of which are incorporated herein by reference.

### BACKGROUND

(i) Technical Field

The present invention relates to a manufacturing method of a semiconductor device.

(ii) Related Art

A semiconductor device such as an FET (Field Effect Transistor) may be used as an element for amplifying an output of a high frequency wave. The semiconductor device may have a passivation layer on a surface of a semiconductor layer. Japanese Patent Application Publications Nos. 7-273107 and 2007-273649 disclose a semiconductor device having an insulating layer including silicon on a semiconductor layer. There is a demand for enlarging a thickness of the passivation layer for effective passivation. There is a demand for increasing a layer-forming rate of the passivation layer for efficient of a manufacturing process.

### SUMMARY

With a conventional technology, when a thick passivation layer is formed speedily, the passivation layer may be peeled. It is an object to provide a manufacturing method of a semiconductor device establishing an efficient manufacturing process and restraining a peeling of a passivation layer.

According to an aspect of the present invention, there is provided a manufacturing method of a semiconductor device including: forming a metal layer including gold; growing a first silicon nitride layer in contact with the metal layer by a plasma-enhanced vapor deposition method; growing a second silicon nitride layer in contact with the first silicon nitride layer at a layer-forming rate higher than that of the first silicon nitride layer, the second silicon nitride layer having a silicon composition ratio smaller than that of the first silicon nitride layer.

### BRIEF DESCRIPTION OF THE DRAWINGS

FIG. 1 illustrates a plane view of a semiconductor device;

FIG. 2A and FIG. 2B illustrate a cross sectional view of a semiconductor device in accordance with a comparative embodiment;

FIG. 3 illustrates a cross sectional view of the semiconductor device in accordance with the comparative embodiment;

FIG. 4 illustrates results of an experiment;

FIG. 5A and FIG. 5B illustrate a cross sectional view of a semiconductor device in accordance with a first embodiment;

FIG. 6A and FIG. 6B illustrate a cross sectional view for describing a manufacturing method of the semiconductor device in accordance with the first embodiment;

FIG. 7A and FIG. 7B illustrate a cross sectional view for describing a manufacturing method of the semiconductor device in accordance with the first embodiment;

FIG. 8A through FIG. 8C illustrate a cross sectional view for describing a manufacturing method of the semiconductor device in accordance with the first embodiment; and

FIG. 9A and FIG. 9B illustrate a cross sectional view for describing a manufacturing method of the semiconductor device in accordance with the first embodiment.

### DETAILED DESCRIPTION

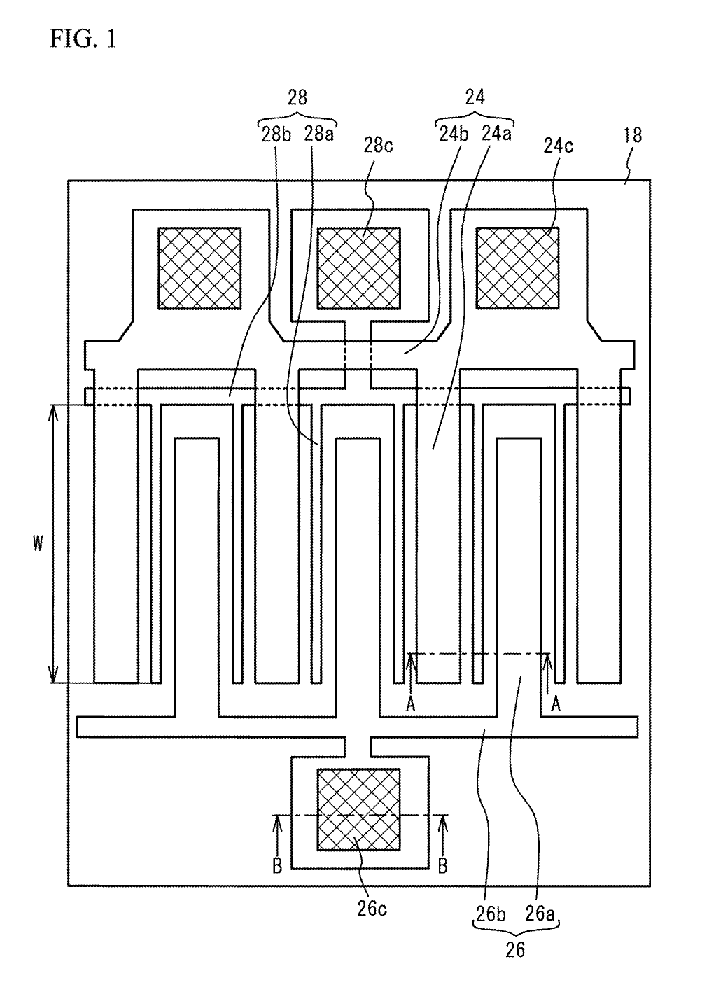

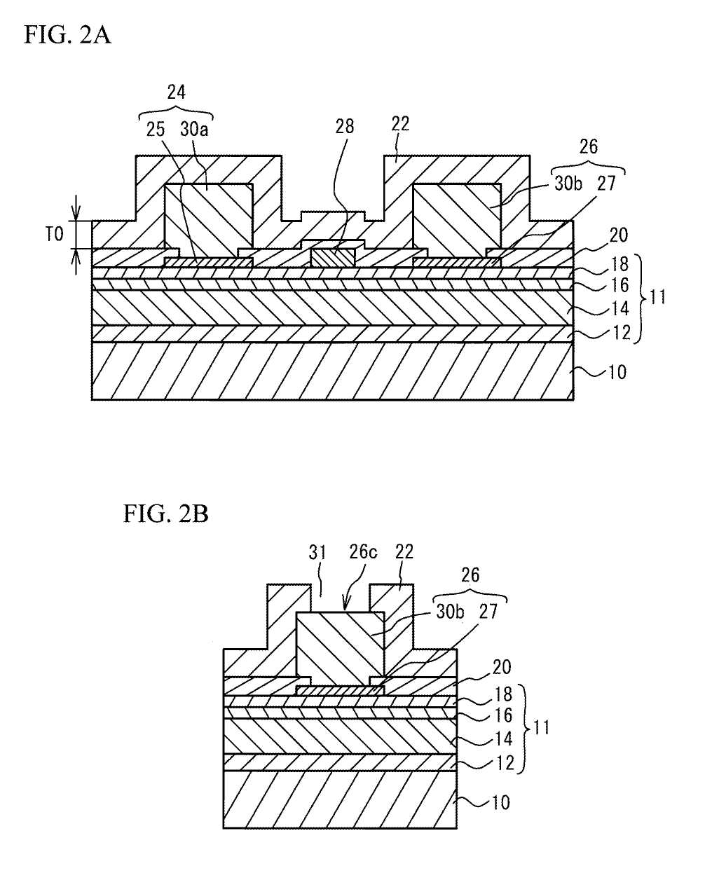

A description will be given of a comparative example before describing embodiments. FIG. 1 illustrates a plane view of a semiconductor device in accordance with the comparative embodiment. FIG. 2A and FIG. 2B illustrate a cross sectional view of the semiconductor device. FIG. 2A illustrates a cross sectional view taken along a line A-A of FIG. 1. FIG. 2B illustrates a cross sectional view taken along a line B-B of FIG. 1. In FIG. 1, a silicon nitride (SiN) layer 20 and a silicon nitride layer 22 are seen through, and a source electrode 24, a drain electrode 26 and a gate electrode 28 are illustrated. The number of the electrode of FIG. 1 is an example and is changeable. Mesh regions indicate a source pad 24c, a drain pad 26c and a gate pad 28c.

As illustrated in FIG. 1A, FIG. 2A and FIG. 2B, the semiconductor device has a substrate 10, a semiconductor layer 11, the source electrode 24, the drain electrode 26, the gate electrode 28, the silicon nitride layer 20 and the silicon nitride layer 22.

The source electrode 24 is a comb electrode having a source finger 24a and a connection portion 24b. The drain electrode 26 is a comb electrode having a drain finger 26a and a connection portion 26b. The source electrode 24 and the drain electrode 26 face with each other so that the source finger 24a and the drain finger 26a are alternately arrayed. The gate electrode 28 has a gate finger 28a and a connection portion 28b. The gate finger 28a is arrayed between the source finger 24a and the drain finger 26a. In a region where the source finger 24a and the connection portion 28b of the gate electrode 28 are overlapped with each other and a region where the connection portion 24b and the connection portion 28b are overlapped with each other, the source finger 24a and the connection portion 24b have a an air bridge structure, and the connection portion 28b is arranged under the source finger 24a and the connection portion 24b. A part of the source electrode 24, a part of the drain electrode 26, and a part of the gate electrode 28 are exposed from an opening region of the silicon nitride layer 22. The exposed part of the source electrode 24 acts as the source pad 24c. The exposed part of the drain electrode 26 acts as the drain pad 26c. The exposed part of the gate electrode 28 acts as the gate pad 28c. The source pad 24c, the drain pad 26c and the gate pad 28c are used for an electrical connection between the semiconductor device and an outer component.

As illustrated in FIG. 2A and FIG. 2B, the semiconductor layer 11 is provided on an upper face of the substrate 10. The semiconductor layer 11 includes a barrier layer 12, a channel layer 14, an electron supply layer 16 and a cap layer 18. The barrier layer 12, the channel layer 14, the electron supply layer 16 and the cap layer 18 are laminated in order from the side of the substrate 10. The silicon nitride layer 20, a source electrode layer 25, a drain electrode layer 27, and the gate electrode 28 are provided on an upper face of the cap layer 18. The source electrode layer 25 and the drain electrode layer 27 act as an ohmic electrode. A wiring 30a is provided on an upper face of the source electrode layer 25. A wiring 30b is provided on an upper face of the drain electrode layer 27. The wiring 30a and the wiring 30b are made of gold (Au). The source electrode 24 includes the source electrode layer 25 and the wiring 30a. The drain electrode 26 includes the drain electrode layer 27 and the wiring 30b. The silicon nitride layer 20 and the silicon nitride layer 22 are provided in this order on the semiconductor layer 11. A thickness T0 of the silicon nitride layer 22 is, for example, 600 nm. The silicon nitride layer 20 and the silicon nitride layer 22 cover the gate electrode 28.

As illustrated in FIG. 2A, the silicon nitride layer 22 is in contact with the wiring 30a and the wiring 30b, and covers the wiring 30a and the wiring 30b in the cross section taken along the line A-A of FIG. 1. On the other hand, as illustrated in FIG. 2B, the silicon nitride layer 22 has an opening region 31 exposing a surface of the wiring 30b of the drain electrode 26 in the cross section taken along the line B-B of FIG.1. The exposed part of the wiring 30b acts as the drain pad 26c as mentioned above.

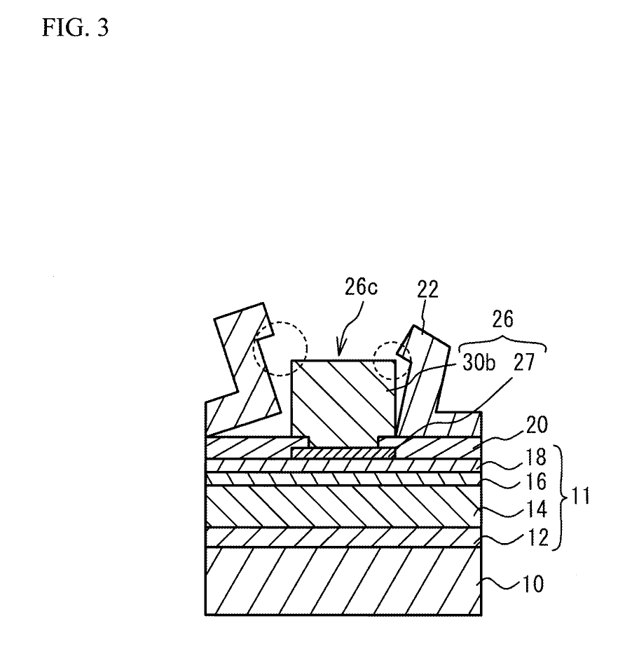

The silicon nitride layer 20 acts as a passivation layer with respect to the semiconductor layer 11. The silicon nitride layer 22 acts as a passivation layer with respect to the gate electrode 28, the wiring 30a and the wiring 30b. The passivation layer restrains a short and improves moisture resistance. However, it is preferable that the silicon nitride layer 22 has a given thickness in order to improve the moisture resistance. In a case where the silicon nitride layer 22 having a large thickness is formed, it is preferable that a layer-forming rate of the silicon nitride layer 22 is enlarged in order to improve an efficiency of a manufacturing process. However, when a composition ratio Si/N is small, there is a problem that the silicon nitride layer 22 tends to be peeled from the wiring 30a or the wiring 30b. FIG. 3 illustrates a cross sectional view of a semiconductor device in which a silicon nitride layer is peeled. FIG. 3 illustrates a cross sectional view taken along the line B-B of FIG. 1. Here, a composition ratio means an atomic ratio.

As indicated with a dotted circle in FIG. 3, the silicon nitride layer 22 tends to be peeled from an edge portion of the opening region 31. FIG. 3 illustrates a case where the silicon nitride layer 22 is peeled from the wiring 30b. Similarly, there is a case where the silicon nitride layer 22 is peeled from the wiring 30a. There is a case where the silicon nitride layer 22 is peeled from the wiring 30a or the wiring 30b in a region other than the opening region. For example, the silicon nitride layer 22 tends to be peeled in a high pressure washing process (for example, a jet scrubber process) because the silicon nitride layer 22 is subjected to a physical force. There is case where the silicon nitride layer 22 is peeled because of added force by water, because the water may be used in a dicing process for cutting the substrate 10 and the semiconductor layer 11. When the silicon nitride layer 22 is peeled, a contaminated material, the water and so on are adhered to a peeling area of the wiring 30a or the wiring 30b. For example, when the water intrudes into an interface between the silicon nitride layer 22 and the wiring 30a or the wiring 30b, the wiring 30a or the wiring 30b may be caused corroded. A contaminated material such as a broken piece which has electro conductivity made in the dicing process may be adhered to the semiconductor layer 11. An electrical short may occur because of the adherence of the contaminated material. After the semiconductor device is fabricated, the silicon nitride layer 22 may be peeled because of heat or impact added to the semiconductor device during mounting of the semiconductor device on an electronic device. For effective passivation, there is a demand on improving the adhesiveness between the silicon nitride layer, the wiring 30a and the wiring 30b.

A description will be given of an experiment. The experiment demonstrates whether the adhesiveness can be changed according to the composition ratio of Si in a silicon nitride layer. First, a sample is described.

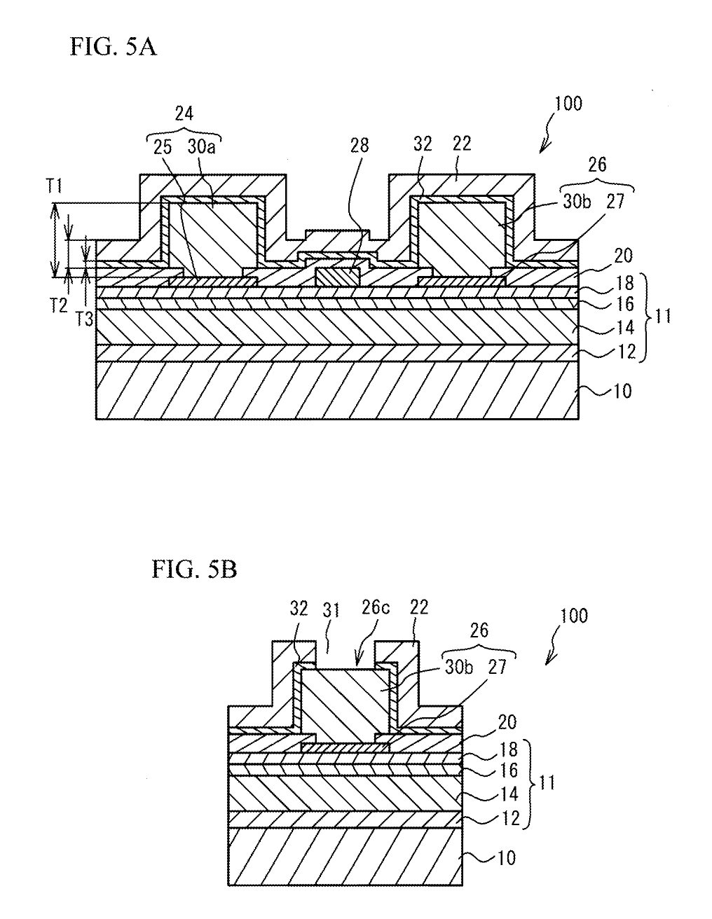

The sample was a semiconductor device illustrated in FIG. 1, FIG. 5A and FIG. 5B. A size of the semiconductor device was as follows.

Chip size: 0.5×2 mm²
Unit gate width W (illustrated in FIG. 1): 300 μm
Growth conditions of the silicon nitride layer 22 were as follows.
Device: Parallel plate plasma CVD (Chemical Vapor Deposition) device
Power density: 0.07 W/cm²
Atmosphere pressure: 1 Torr (133.3 Pa)
Temperature in a furnace: 300 degrees C.
Samples of which composition ratio (Si/N) of silicon (Si) with respect to nitrogen (N) in the silicon nitride layer 22 was changed in a range of 0.6 to 1 were prepared. The thickness T3 of the silicon nitride layer 22 was set to be 5 nm and 50 nm with respect to each composition ratio. The number of samples was 200 with respect to each composition ratio and each thickness. In the experiment, the samples were subjected to a thermal shock experiment, after that, the samples were subjected to a peeling experiment. The number of samples of the 200 samples in which the silicon nitride layer 22 is peeled from a part of which surface is Au such as the wiring 30a or 30b was examined. In the thermal shock experiment, a cycle in which a temperature is increased to 350 degrees C. and decreased to a room temperature in two minutes was repeated three times. In the peeling experiment, a tape is adhered to the samples, after that, the tape is peeled, and it was observed whether a peeling occurred or not in the silicon nitride layer 22.

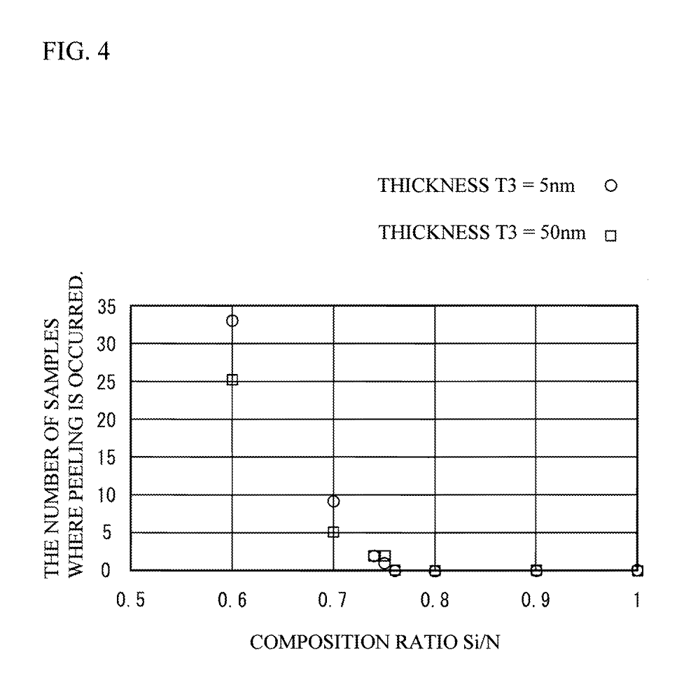

FIG. 4 illustrates results of the experiment. A horizontal axis indicates the composition ratio Si/N. A vertical axis indicates the number of samples of the 200 samples in which a peeling occurred. Circles indicate results of samples having the thickness T3 of 5 nm. Squares indicate results of samples having the thickness T3 of 50 nm.

As illustrated in FIG. 4, the higher the composition ratio Si/N was, the fewer the number of the peeled sample was. In particular, when the composition ratio Si/N was 0.8 or more, the number of the peeled sample was zero. As apparent from the result of the composition ratio Si/N=0.6, the larger the thickness of a sample was, the fewer the number of the peeled sample was, when the composition ratio Si/N was equal to each other. Accordingly, the higher the composition ratio of Si in the silicon nitride layer was, the more the adhesiveness between the silicon nitride layer and the wiring 30a or the wiring 30b was improved. The larger the thickness was, the more the adhesiveness was improved.

From the knowledge, it is understood that: the adhesiveness between a metal layer made of Au and a silicon nitride layer is improved when the Si composition ratio of the silicon nitride layer in contact with the metal layer is increased; and the adhesiveness between the silicon nitride layer and the metal layer is improved when the Si composition ratio is reduced and the silicon nitride layer is formed at a high layer-forming rate; and the thickness allows high humidity resistance of the silicon nitride layer. In order to form a silicon nitride layer having a high composition ratio of Si, it is necessary to reduce the layer-forming rate. This is because there is a problem that a material (for example amorphous silicon) other than a silicon nitride may be precipitated if a silicon nitride layer having a high Si composition ratio is formed at a high layer-forming rate. In order to reduce the layer-forming rate of a silicon nitride layer, a flow rate of a raw material gas may be reduced. In addition, it is effective to reduce a power density that is a ratio between electrical power applied in a CVD method and an area of an electrode to which the electrical power is applied.

### First Embodiment

FIG. 5A and FIG. 5B illustrate a cross sectional view of a semiconductor device in accordance with a first embodiment. A plane view of the semiconductor device is the same as that of FIG. 1. FIG. 5A illustrates a cross sectional view taken along the line A-A of FIG. 1. FIG. 5B illustrates a cross sectional view taken along the line B-B of FIG. 1. The structure described with reference to FIG. 1 to FIG. 2B is omitted in the embodiment.

As illustrated in FIG. 5A and FIG. 5B, a semiconductor device 100 in accordance with the first embodiment has a silicon nitride layer 32. In concrete, the silicon nitride layer 32 acting as a first silicon nitride layer is formed on the silicon nitride layer 20. The silicon nitride layer 22 acting as a second silicon nitride layer is formed on the silicon nitride layer 32. The silicon nitride layer 32 is formed so as to overlap with the silicon nitride layer 22. That is, the silicon nitride layer 32 is in contact with the side face and the upper face of the wirings 30a and 30b. The silicon nitride layer 22 is in contact with the silicon nitride layer 32 but is not in contact with the wiring 30a or 30b. As illustrated in FIG. 5B, at the cross section taken along the line B-B of FIG. 1, the silicon nitride layer 22 and the silicon nitride layer 32 have the opening region 31 exposing the surface of the wiring 30b.

The substrate 10 is made of SiC (silicon carbide), Si, sapphire or the like. The barrier layer 12 is, for example, made of aluminum nitride (AlN) having a thickness of 300 nm. The channel layer 14 is, for example, made of gallium nitride (i-GaN) having a thickness of 1000 nm. The electron supply layer 16 is, for example, made of aluminum gallium nitride (AlGaN) having a thickness of 300 nm. The cap layer 18 is, for example, made of non-doped gallium nitride having a thickness of 5 nm. The semiconductor device 100 is an FET having a nitride semiconductor. The wirings 30a and 30b are a wiring coupled to the source electrode layer 25 and the drain electrode layer 27 of the FET respectively.

For example, the source electrode layer 25 and the drain electrode layer 27 have a structure in which titanium (Ti) and aluminum (Al) are laminated in order from the side of the cap layer 18. The wirings 30a and 30b are, for example, made of Au having a thickness of 3 μm. For example, the gate electrode 28 has a structure in which nickel (Ni) and Au are laminated in order from the side of the cap layer 18. The thickness of the silicon nitride layer 20 is, for example, 50 nm to 80 nm. A composition of the Au in the wirings 31a and 30b and the gate electrode 28 is 90% or higher. In the case of this embodiment, the Au composition (purity of Au) is 99.9%.

The Si composition ratio of the silicon nitride layer 32 is higher than that of the silicon nitride layer 22. For example, the composition ratio Si/N of the silicon nitride layer 22 is 0.75 or less. The composition ratio Si/N of the silicon nitride layer 32 is 0.8 or more. Total thickness T1 of the silicon nitride layer 22 and the silicon nitride layer 32 is, for example, 600 nm and is the same as the thickness T0 of the comparative example. The thickness T2 of the silicon nitride layer 22 is, for example, 550 nm. The thickness T3 of the silicon nitride layer 32 is, for example, 50 nm. The thickness T2 of the silicon nitride layer 22 and the thickness T3 of the silicon nitride layer 32 are changeable. However, the thickness T2 of the silicon nitride layer 22 is larger than the thickness T3 of the silicon nitride layer 32.

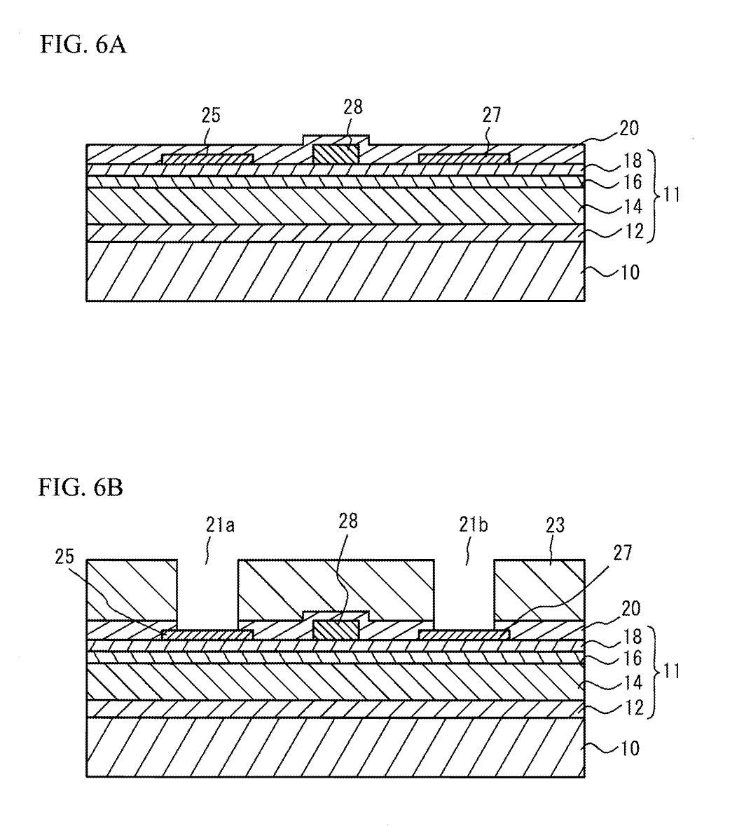

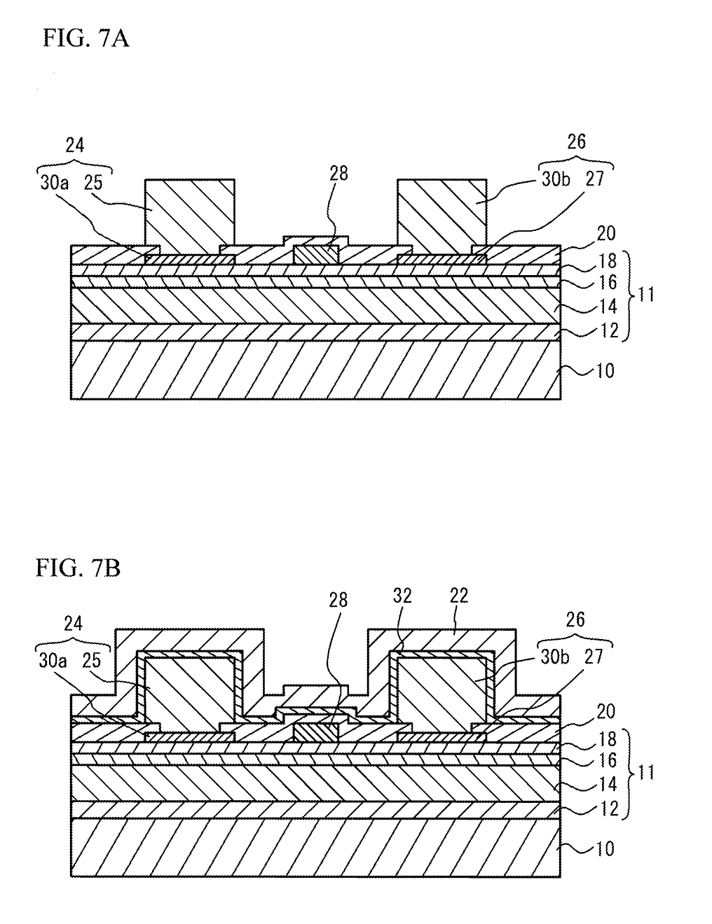

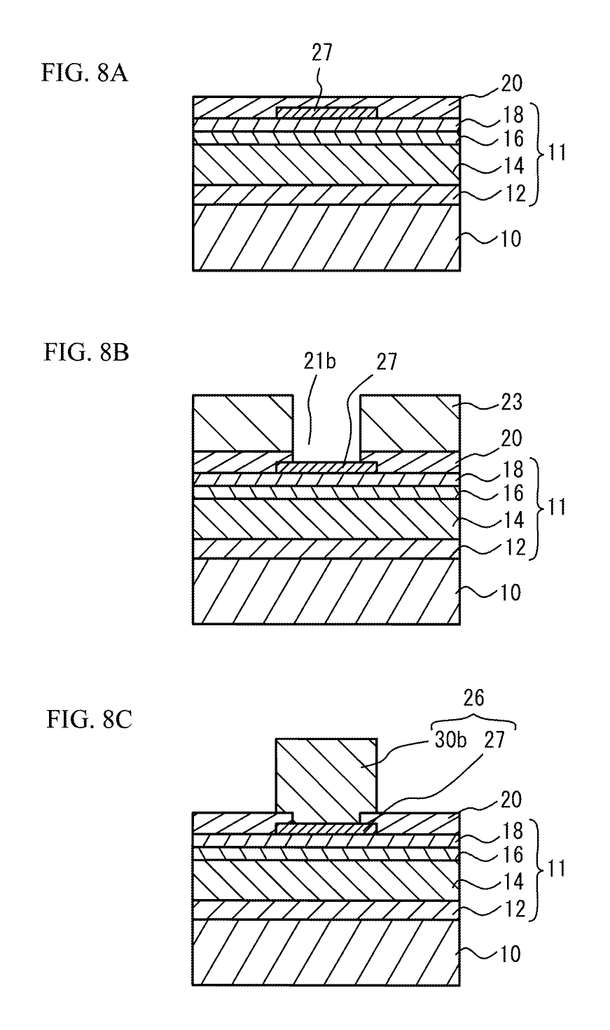

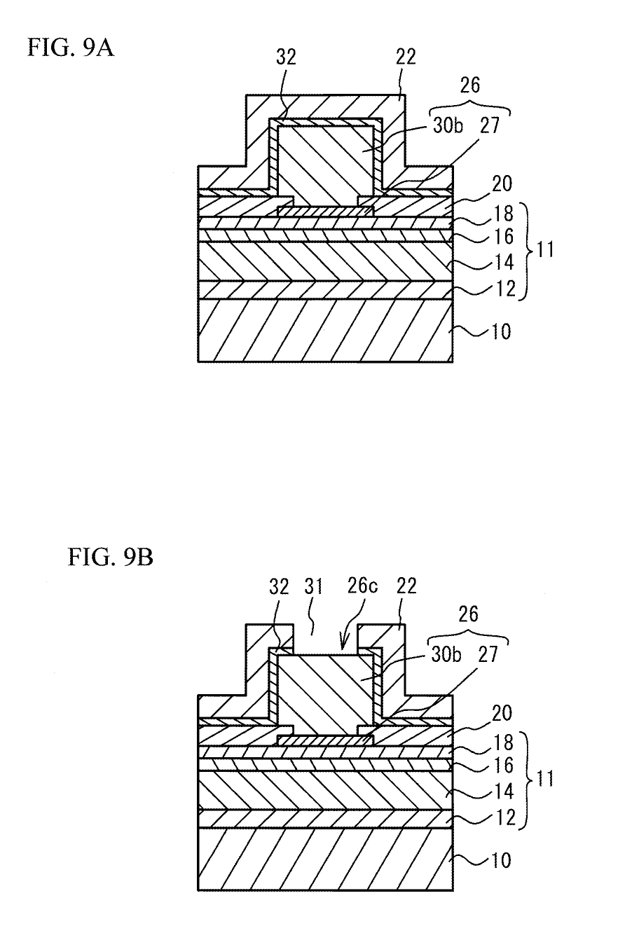

Next, a description will be given of a manufacturing method of the semiconductor device in accordance with the first embodiment. FIG. 6A through FIG. 7B illustrate cross sectional views for describing the manufacturing method of the semiconductor device in accordance with the first embodiment, and correspond to the A-A cross section of FIG. 1. FIG. 8A through FIG. 9B illustrate cross sectional views for describing the manufacturing method of the semiconductor device in accordance with the first embodiment, and correspond to the B-B cross section of FIG. 1.

The barrier layer 12, the channel layer 14, the electron supply layer 16 and the cap layer 18 are epitaxially grown from the side of the substrate 10 with use of a MOCVD (Metal Organic Chemical Vapor Deposition) method or the like. And, the source electrode layer 25, the drain electrode layer 27 and the gate electrode 28 are formed on the cap layer 18 with use of a vapor deposition method, a lift-off method or the like.

As illustrated in FIG. 6A and FIG. 8A, the silicon nitride layer 20 is formed on the cap layer 18 so as to cover the source electrode layer 25, the drain electrode layer 27 and the gate electrode 28. As illustrated in FIG. 6B and FIG. 8B, a resist 23 is formed on the silicon nitride layer 20. An opening region 21a and an opening region 21b are formed in the silicon nitride layer 20 with use of an etching method or the like. The source electrode layer 25 is exposed through the opening region 21a. The drain electrode layer 27 is exposed through the opening region 21b.

As illustrated in FIG. 7A and FIG. 8C, the wiring 30a is formed on the upper face of the source electrode layer 25, and the wiring 30b is formed on the upper face of the drain electrode layer 27 respectively with use of an electrolytic plating method, a non-electrolytic plating method or the like.

As illustrated in FIG. 7B and FIG. 9A, the silicon nitride layer 32 is formed so as to cover the silicon nitride layer 20, the wiring 30a and the wiring 30b with use of a CVD method. And, the silicon nitride layer 22 is formed on the silicon nitride layer 32.

Layer-forming conditions of forming the silicon nitride layer 32 are as follows. It is necessary to reduce the layer-forming rate in order to form a silicon nitride layer having a high Si/N ratio. An example of the layer-forming condition is as follows.
Flow rate of raw material gas: SiH₄:NH₃:carrier gas is 2 to less than 10:0 to 1:1000 sccm (3.38×10⁻³ to less than 1.69×10⁻²:0 to 1.69×10⁻³:1.69 Pa·m³/s)
And, there are two methods as follows, in concrete.
Method 1:
SiH₄ is used as a silicon raw material. Nitrogen gas (N₂) is used as a nitrogen raw material and the carrier gas. Helium (He) is used as the carrier gas. A flow amount ratio is, for example, SiH₄:carrier gas=5:1000 sccm (8.45×10⁻³:1.69 Pa·m³/s). A flow amount ratio of nitrogen (N₂) and helium (He) is, for example, 1:4.
Method 2:
SiH₄ is used as a silicon raw material. NH₃ is used as a nitrogen raw material. Nitrogen (N₂) and helium (He) are used as the carrier gas. Flow amount ratio is, for example, SiH₄:NH₃:carrier gas=5:0.5:1000 sccm (8.45×10⁻³:8.45×10⁻⁴:1.69 Pa·m³/s). A flow amount ratio of nitrogen (N₂) and helium (He) is, for example, 1:4.
The following conditions are common in the method 1 and the method 2.
Device: Parallel plate plasma CVD device
Power density: 0.07 W/cm²
Frequency: 13.56 MHz
Atmosphere pressure: 1 Torr (133.3 Pa)
Temperature in a furnace: 300 degrees C.
Layer-forming rate: 10 nm/min
[Layer-forming rate of the silicon nitride layer 32] It is preferable that the layer-forming rate is 10 nm/min or less because when the layer-forming rate is high, amorphous silicon or the like may be precipitated as mentioned above. On the other hand, when the layer-forming rate is excessively low, a manufacturing efficiency may be degraded. Therefore, it is preferable that the layer-forming rate is 8 nm/min or more. That is, it is preferable that the layer-forming rate of the silicon nitride layer 32 is selected from a range of 10 nm/min to 8 nm/min.

With respect to the silicon nitride layer 22, a condition for forming a given thickness effectively is set. As mentioned above, it is difficult to form a silicon nitride layer having a high Si composition ratio with a high layer-forming rate. And so, with respect to the silicon nitride layer 22, a condition of a Si composition ratio lower than the silicon nitride layer 32 is set. A layer-forming condition for forming the silicon nitride layer 22 is as follows. The layer-forming condition in common with the silicon nitride layer 32 is omitted. As an example, the following ranges may be set.
Flow rate: SiH₄:NH₃:carrier gas=10 to 20:2 to 10:1000 sccm (1.69×10⁻² to 3.38×10⁻²:3.38×10⁻³ to 1.69×10⁻²:1.69 Pa·m³/s)

In concrete, the following conditions are set.
SiH₄:NH₃:carrier gas=15:10:1000 sccm (2.535×10⁻²:1.69×10⁻²:1.69 Pa·m³/s)
Power density: 0.21 W/cm²
Layer-forming rate: 40 nm/min
[layer-forming rate of the silicon nitride layer 22] It is preferable that the layer-forming rate of the silicon nitride layer 22 is 40 nm/min in order to improve the manufacturing efficiency.

As illustrated in FIG. 9B, the opening region 31 is formed by removing the silicon nitride layer 22 and the silicon nitride layer 32 on the wiring 30b. The surface of the wiring 30b acting as the drain pad 26c is exposed through the opening region 31. At least of a part of the surface of the wiring 30b has only to be exposed through the opening region 31. After that, a high pressure washing process such as a jet scrubber process is performed. After the high pressure washing process, a dicing process for dividing a wafer into each chip is performed. With the processes, the semiconductor device 100 in accordance with the first embodiment is fabricated.

In accordance with the first embodiment, the silicon nitride layer 32 in contact with the wirings 30a and 30b made of Au has the Si composition ratio higher than that of the silicon nitride layer 22. Therefore, as illustrated in FIG. 4, the adhesiveness between the silicon nitride layer 32 and the wirings 30a and 30b is enhanced.

The growing process of the silicon nitride layers 22 and 32 uses SiH₄ and NH₃ as a raw material and uses the CVD method in order to form the above-mentioned silicon nitride layers 22 and 32. The flow rate of the SiH₄ and the flow rate of NH₃ in the growing process of the silicon nitride layer 32 are respectively lower than the flow rate of SiH₄ and the flow rate of NH₃ in the growing process of the silicon nitride layer 22. That is, the growing process of the silicon nitride layer 22 is performed under a condition that the flow rate of silicon raw material gas (SiH₄) and a ratio of the nitrogen raw material (NH₃) with respect to the silicon raw material are higher than in the growing process of the silicon nitride layer 32. In concrete, as mentioned above, a flow mount ratio R1 of SiH₄ with respect to the carrier gas (He and N₂) is 0.002 or more and is 0.01 or less in the growing process of the silicon nitride layer 32. A flow amount ratio R2 of NH₃ with respect to the carrier gas is 0 or more and is 0.001 or less. A flow amount ratio R3 of SiH₄ with respect to the carrier gas (He and N₂) in the growing process of the silicon nitride layer 22 is 0.01 or more and is 0.02 or less. A flow amount ratio R4 of NH₃ with respect to the carrier gas is 0.002 or more and is 0.01 or less. The flow amount ratio R1 may be 0.003 or more, and 0.009 or less. The flow amount ratio R2 may be 0.0001 or more, and 0.0009 or less. The flow amount ratio R3 may be 0.012 or more, and 0.018 or less. The flow amount ratio R4 may be 0.003 or more, and 0.009 or less. In this way, the composition ratio Si/N of the silicon nitride layer 32 gets higher. The manufacturing process gets more efficient, because the flow rate of the raw material gas of the silicon nitride layer 22 (SiH₄ and NH₃) is higher than that of the silicon nitride layer 32. Therefore, in accordance with the first embodiment, the peeling of the silicon nitride layer 32 acting as a passivation layer is restrained, and the manufacturing process gets more efficient. The carrier gas may be a mixed gas of a noble gas such as He or Argon (Ar) and N₂, or a noble gas.

As illustrated in FIG. 4, the peeling of the silicon nitride layer is effectively restrained, when the thickness of the silicon nitride layer is 5 nm or 50 nm, and the composition ratio Si/N is 0.8 or more. It is therefore preferable that the thickness T3 of the silicon nitride layer 32 is 5 nm or more, and the composition ratio Si/N of the silicon nitride layer 32 is 0.8 or more. The composition ratio Si/N of the silicon nitride layer 22 may be 0.85 or more, or may be 0.9 or more.

In order to increase the Si composition ratio, the flow rate of SiH₄ and NH₃ is reduced, and the power density of the CVD method is reduced. In this case, the layer-forming rate of the silicon nitride layer is reduced. For example, the layer-forming rate of the silicon nitride layer 32 is 10 nm/min or less. On the other hand, the layer-forming rate of the silicon nitride layer 22 is, for example, 40 nm/min or more. In this way, the silicon nitride layer 22 grows at the layer-forming rate higher than that of the silicon nitride layer 32. In order to restrain the peeling and make the manufacturing process more efficient, the silicon nitride layer 32 having a high Si composition ratio is provided in contact with the wirings 30a and 30b, and the silicon nitride layer 22 having a low Si composition ratio is provided on the silicon nitride layer 32. In order to increase the layer-forming rate of the silicon nitride layer 22 and make the manufacturing process more efficient, it is preferable that the composition ratio Si/N of the silicon nitride layer 22 is 0.75 or less. The composition ratio of the silicon nitride layer 22 may be 0.7 or less, 0.6 or less, or 0.5 or less.

In order to make the manufacturing process more efficient, it is preferable that the thickness of the silicon nitride layer 22 having a high layer-forming rate is larger than that of the silicon nitride layer 32. And, it is preferable that the thickness T3 of the silicon nitride layer 32 is enlarged so that the effect of restraining the peeling is sufficiently established. For example, the thickness T2 of the silicon nitride layer 22 may be 100 nm or more, and the thickness T3 of the silicon nitride layer 32 may be 5 nm or more and 100 nm or less. The thickness T2 of the silicon nitride layer 22 may be twice or more, five times or more, or ten times or more as much as the thickness T3 of the silicon nitride layer 32. In order to improve humidity resistance, it is preferable that the total thickness T1 of the silicon nitride layer 22 and the silicon nitride layer 32 is enlarged. This allows more efficient of the manufacturing process and high humidity resistance.

The wiring 30a is coupled to the source electrode 24 of the FET. The wiring 30b is coupled to the drain electrode 26 of the FET. Therefore, in accordance with the first embodiment, the reliability of the FET is improved. In particular, in the opening region 31, the peeling of the silicon nitride layer 32 is restrained. Therefore, the reliability of the semiconductor device can be improved more effectively. And, even if the semiconductor device is subjected to a mechanical force such as a jet scrubber process and is subjected to a process using water, the peeling of the silicon nitride layer 32 is restrained. And, as illustrated in FIG. 4, the silicon nitride layer having a high Si/N ratio is difficult to be peeled in a thermal shock test. Therefore, the peeling of the silicon nitride layer 32 is restrained even if the fabricated semiconductor device is used.

An ECR (Electronic Cyclotron Resonance) plasma CVD method, an ICP (Inductively Coupled Plasma) CVD method or the like other than the parallel plate plasma CVD method may be used as the plasma-enhanced CVD method.

The embodiment has an effect of effectively restraining a peeling of a silicon nitride layer on a metal layer of which surface is made of Au. That is, the same effect is achieved with respect to another electrode other than the wirings 30a and 30b, if the electrode has a surface made of Au. A nitride semiconductor layer other than GaN, AlN, or AlGaN may be used as a semiconductor layer. The nitride semiconductor is a semiconductor including nitrogen. For example, the nitride semiconductor is indium nitride (InN), indium gallium nitride (InGaN), indium aluminum nitride (InAlN), or aluminum indium gallium nitride (AlInGaN). A semiconductor including arsenic (As) may be used as the semiconductor. As an example, gallium arsenic (GaAs), aluminum arsenic (AlAs), indium arsenic (InAs), indium gallium arsenic (InGaAs), aluminum gallium arsenic (AlGaAs), aluminum indium gallium arsenic (AlInGaAs) or the like may be used as the semiconductor.

The present invention is not limited to the specifically disclosed embodiments and variations but may include other embodiments and variations without departing from the scope of the present invention.

What is claimed is:

1. A manufacturing method of a semiconductor device comprising:
forming a metal layer having a surface containing gold;
growing a first silicon nitride layer in contact with the metal layer by a plasma-enhanced vapor deposition method;
growing a second silicon nitride layer in contact with the first silicon nitride layer by a plasma-enhanced vapor deposition method at a layer-forming rate higher than that of the first silicon nitride layer, the second silicon nitride layer having a silicon composition ratio smaller than that of the first silicon nitride layer.

2. The method as claimed in claim 1, wherein the second silicon nitride layer is grown under a condition that a flow rate of a silicon raw material gas is higher than that of the first silicon nitride layer, and a ratio of a nitrogen raw material gas with respect to the silicon raw material gas is higher than that of the first silicon nitride layer.

3. The method as claimed in claim 1, wherein a high frequency power density of the plasma-enhanced vapor deposition method in the growling of the first silicon nitride layer is lower than that in the growing of the second silicon nitride layer.

4. The method as claimed in claim 2, wherein:
a flow amount ratio of a silane with respect to a carrier gas in the growing of the first silicon nitride layer is 0.002 or more, and less than 0.01; and
a flow amount ratio of an ammonia with respect to the carrier gas in the growing of the first silicon nitride layer is 0 or more, and 0.001 or less.

5. The method as claimed in claim 4, wherein:
a flow amount ratio of a silane with respect to a carrier gas in the growing of the second silicon nitride layer is 0.01 or more, and 0.02 or less; and
a flow amount ratio of an ammonia with respect to the carrier gas in the growing of the second silicon nitride layer is 0.002 or more, and 0.01 or less.

6. The method as claimed in claim 1, wherein:
a silicon composition ratio with respect to a nitrogen Si/N in the first silicon nitride layer is 0.8 or more; and
a silicon composition ratio with respect to a nitrogen Si/N in the second silicon nitride layer is 0.75 or less.

7. The method as claimed in claim 1 further comprising forming an opening region in the first silicon nitride layer and the second silicon nitride layer, the opening region exposing the metal layer.

8. The method as claimed in claim 1, wherein a thickness of the second silicon nitride layer is larger than that of the first silicon nitride layer.

9. The method as claimed in claim 1 further comprising performing a high-pressure washing after the growing of the second silicon nitride layer.

10. The method as claimed in claim 1, wherein a layer-forming rate of the first silicon nitride layer is 10 nm/min or less.

11. The method as claimed in claim 1, wherein a layer forming rate of the first silicon nitride layer is 10 nm/min to 8 nm/min.

12. The method as claimed in claim 1, wherein a layer-forming rate of the second silicon nitride layer is 40 nm/min or less.

13. The method as claimed in claim 1, wherein:
a layer-forming rate of the first silicon nitride layer is 10 nm/min to 8 nm/min; and
a layer-forming rate of the second silicon nitride layer is 40 nm/min or more.

14. The method as claimed in claim 1, wherein:
a gold composition of the surface of the metal layer is 90% or higher.

15. The method as claimed in claim 14, wherein:
the gold composition of the surface of the metal layer is 99.9% or higher.

16. The method as claimed in claim 7 further comprising performing a high-pressure washing after the forming the opening region.
